(19) United States
(12) Patent Application Publication
(10) Pub. No.: US 2003/0103336 A1
(43) Pub. Date: Jun. 5, 2003

(54) Packaging architecture for a multiple array transceiver using a flexible cable and stiffener for customer attachment

(75) Inventors: Johnny R. Brezina, Austin, TX (US); Brian M. Kerrigan, Austin, TX (US); Gerald D. Malagrino JR., Rochester, MN (US); James R. Moon, Oronoco, MN (US)

Correspondence Address: Frank C. Nicholas, CARDINAL LAW GROUP, Suite 2000, 1603 Orrington Avenue, Evanston, IL, 60201, US

(73) Assignee: International Business Machines Corporation, Armonk, NY (US)

(21) Appl. No.: 10/006,838

(22) Filed: Dec. 5, 2001

(51) Int. Cl. H05K 1/14

(52) U.S. Cl. 361/743

(57) ABSTRACT

The packaging architecture for a multiple array transceiver using a flexible cable and stiffener for customer attachment of the present invention provides a 90 degree transition between an optical signal input/output at a communication chassis bulkhead, and an provides for a ball grid array attachment to a common host board. The packaging architecture system comprises a forward vertical carrier having an optical converter; a stiffener block, the stiffener block oriented about 90 degrees from the forward vertical carrier; and a flexible cable electrically connecting the optical converter of the forward vertical carrier to a solder ball array aligned with the stiffener block. The multiple array transceiver makes the 90 degree transition within a narrow gap established by industry and manufacturing standards. The multiple array transceiver also provides cooling to the internal electronics through a heat sink attached to the stiffener block, which concurrently mounts and locates the transceiver to the common host board.

### RELATED APPLICATIONS

This application claims priority to U.S. patent application Ser. No. 09/956,771 filed on Sep. 20, 2001 entitled “Fiber Optic Transceiver, Connector, And Method of Dissipating Heat” by Johnny R. Brezina, et al., the entire disclosure of which is incorporated by reference, herein.

This application also relates to the following applications, filed concurrently herewith:

“Optical Alignment In A Fiber Optic Transceiver”, by Johnny R. Brezina, et al. (IBM Docket No. AUS920010689US1);

“External EMI Shield For Multiple Array Optoelectronic Devices”, by Johnny R. Brezina, et al. (IBM Docket No. AUS920010690US1);

“Packaging Architecture For A Multiple Array Transceiver Using A Continuous Flexible Circuit”, by Johnny R. Brezina, et al. (IBM Docket No. AUS920010591US1);

“Flexible Cable Stiffener for An Optical Transceiver”, by Johnny R. Brezina, et al. (IBM Docket No. AUS920010729US1);

“Enhanced Folded Flexible Cable Packaging for Use in Optical Transceivers, by Johnny R. Brezina, et al. (IBM Docket No. AUS920010727US1);

“Apparatus and Method for Controlling an Optical Transceiver”, by Johnny R. Brezina, et al. (IBM Docket No. AUS920010728US1);

“Internal EMI Shield for Multiple Array Optoelectronic Devices”, by Johnny R. Brezina, et al. (IBM Docket No. AUS920010730US1);

“Multiple Array Optoelectronic Connector with Integrated Latch”, by Johnny R. Brezina, et al. (IBM Docket No. AUS920010731US1);

“Mounting a Lens Array in a Fiber Optic Transceiver”, by Johnny R. Brezina, et al. (IBM Docket No. AUS920010733US1);

“Packaging Architecture for a Multiple Array Transceiver Using a Flexible Cable”, by Johnny R. Brezina, et al. (IBM Docket No. AUS920010734US1);

“Packaging Architecture for a Multiple Array Transceiver Using a Winged Flexible Cable for Optimal Wiring”, by Johnny R. Brezina, et al. (IBM Docket No. AUS920010736US1); and

“Horizontal Carrier Assembly for Multiple Array Optoelectronic Devices”, by Johnny R. Brezina, et al. (IBM Docket No. AUS920010763US1).

### TECHNICAL FIELD

The technical field of this disclosure is computer systems, particularly, a packaging architecture for a multiple array transceiver using a flexible cable and stiffener for customer attachment.

### BACKGROUND OF THE INVENTION

Optical signals entering a communications chassis can be converted to electrical signals for use within the communications chassis by a multiple array transceiver. The configuration of optical signal connections entering the communications chassis and the customer's circuit boards within the chassis require a 90-degree direction change in signal path from the optical to the electrical signal. This 90-degree configuration is required due to the right angle orientation between the customer's board and the rear bulkhead of the chassis. Existing multiple array transceiver designs use a number of small parts, such as tiny flexible interconnects with associated circuit cards and plastic stiffeners, to make the 90-degree transition. The size and number of the parts increases manufacturing complexity and expense.

In addition, existing multiple array transceivers are limited in the number of electrical signal paths they can provide between the optical input and the customer's board. It is desirable to provide as many electrical signal paths as possible, because optical fiber can typically provide a greater information flow rate than electrical wire. Industry and company standards further limit the space available for signal paths from the optical input to the customer's board, limiting the space to a narrow gap.

Thermal considerations may also limit the signal carrying capacity of current multiple array transceivers. Heat is generated by electrical resistance as the signals pass through the conductors and as the signals are processed by solid-state chips within the transceivers. Limitations on heat dissipation can limit the data processing speed and reduce transceiver reliability.

It would be desirable to have a packaging architecture for a multiple array transceiver using a folded flexible cable that would overcome the above disadvantages.

### SUMMARY OF THE INVENTION

The packaging architecture for a multiple array transceiver using a flexible cable and stiffener for customer attachment of the present invention provides a 90 degree transition between an optical signal input/output at a communication chassis bulkhead, and an provides for a ball grid array attachment to a common host board. The packaging architecture system comprises a forward vertical carrier having an optical converter; a stiffener block, the stiffener block oriented about 90 degrees from the forward vertical carrier; and a flexible cable electrically connecting the optical converter of the forward vertical carrier to a solder ball array aligned with the stiffener block. The multiple array transceiver makes the 90 degree transition within a narrow gap established by industry and manufacturing standards. The multiple array transceiver also provides cooling to the internal electronics through a heat sink attached to the stiffener block, which concurrently mounts and locates the transceiver to the common host board.

One aspect of the present invention provides a packaging architecture for a multiple array transceiver providing a 90-degree transition between the customer's board and the rear bulkhead of the chassis.

Another aspect of the present invention provides a packaging architecture for a multiple array transceiver with a reduced number of components for manufacturing ease and reduced cost.

Another aspect of the present invention provides a packaging architecture for a multiple array transceiver providing an interconnection containing a very large number of signal paths in a narrow horizontal gap.

Another aspect of the present invention provides a packaging architecture for a multiple array transceiver providing a thermally efficient design with heat flow to a heat sink.

The foregoing and other features and advantages of the invention will become further apparent from the following detailed description of the presently preferred embodiments, read in conjunction with the accompanying drawings. The detailed description and drawings are merely illustrative of the invention, rather than limiting the scope of the invention being defined by the appended claims and equivalents thereof.

### BRIEF DESCRIPTION OF THE DRAWINGS

FIG. 1 shows an isometric diagram of a forward vertical carrier made in accordance with the present invention;

FIGS. 2A & 2B show isometric diagrams of a forward vertical carrier in place in an I/O assembly made in accordance with the present invention; and

FIG. 3 shows an isometric diagram of a packaging architecture for a multiple array transceiver using a continuous flexible cable made in accordance with the present invention.

### DETAILED DESCRIPTION OF THE PRESENTLY PREFERRED EMBODIMENTS

The packaging architecture for a multiple array transceiver using a flexible cable and stiffener for customer attachment of the present invention provides a 90-degree transition between an optical signal input at a communications chassis bulkhead and an interior board within the communications chassis. The multiple array transceiver makes the 90-degree transition within a narrow gap established by industry and manufacturer standards. The multiple array transceiver further provides cooling through a heat sink.

The present invention is shown and described by the following description and figures, and is generally described in the order in which the individual components are assembled during manufacture.

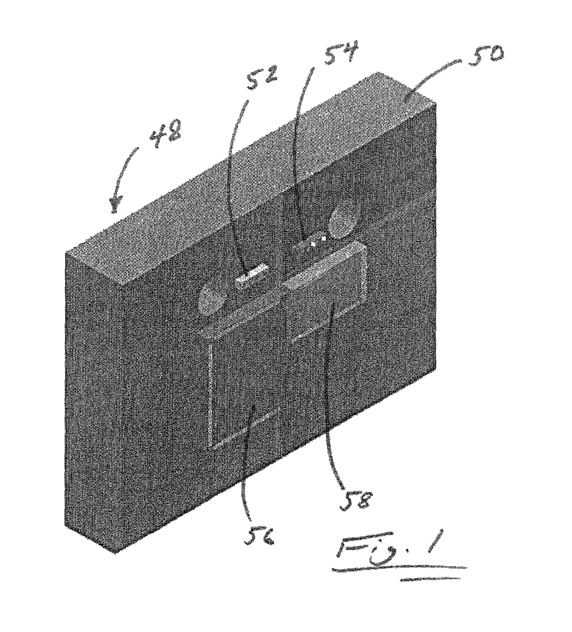

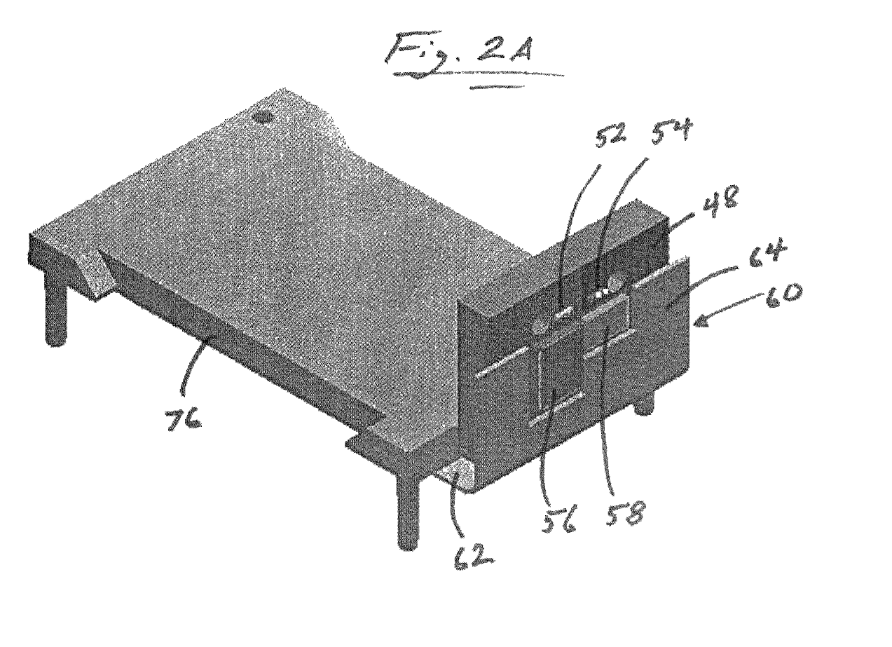

FIG. 1 shows an isometric diagram of a forward vertical carrier made in accordance with the present invention. The forward vertical carrier 48 comprises common substrate carrier 50, laser die 52, photodetector die 54, laser drive amplifier (LDA) 56, and transimpedance amplifier (TIA) 58. The common substrate carrier 50 can be made of any material with good thermal conductivity, such as copper, aluminum nitride, or the like. The common substrate carrier 50 can have a planar face to allow precise mounting of the optical components. The laser die 52 and photodetector die 54 are attached to a common substrate carrier 50 by using standard die bond epoxy material and technique as will be appreciated by those skilled in the art. The laser drive amplifier 56 (LDA) and transimpedance amplifier 58 (TIA) are also die bonded to the substrate carrier 50 in close proximity to the laser die 52 and photodetector die 54 to provide short critical transmission interconnection wire bond lengths. The TIA 58 acts as the photodetector interface chip. The laser die 52 and photodetector die 54 are precisely aligned to provide optimum communication with a fiber optic cable which can be attached to the laser die 52 and photodetector die 54.

The laser die 52 and photodetector die 54 with their associated circuits perform as optical converters to convert a light signal coming into the transceiver to an electrical signal or convert an electrical signal from the transceiver to a light signal. In one embodiment, the optical converters can be lasers only, so that the transceiver only transmits optical signals. In another embodiment, the optical converters can be photodetectors only, so that the transceiver only receives optical signals. In other embodiments, the number of lasers and photodetectors can be predetermined to meet the number of transmit and receive channels desired.

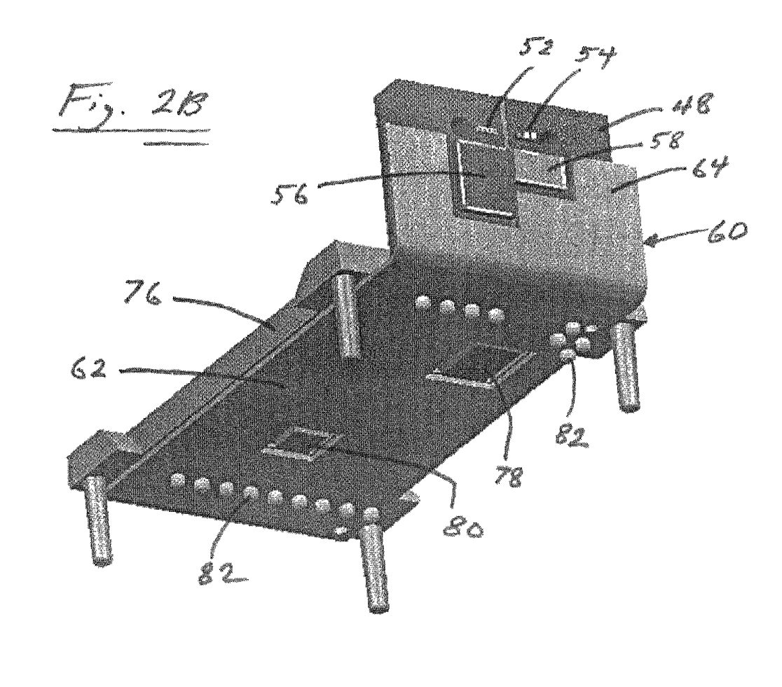

FIGS. 2A & 2B, in which like elements have like reference numbers, show isometric diagrams of a forward vertical carrier in place in an I/O assembly made in accordance with the present invention.

A flexible cable 60 comprises a first circuit portion 62 and a second circuit portion 64. In the assembled multiple array transceiver, the first circuit portion 62 can be generally horizontal and the second circuit portion 64 can be generally vertical, to meet the required 90 degree change in signal path direction. Thus, the first circuit portion 62 is oriented at about a 90-degree angle to the second circuit portion 64.

The flexible cable 60 connects the stiffener block 76 to the forward vertical carrier 48, where the laser die 52 and photodetector die 54 are located. The flexible cable 60 can contain a plurality of conductors carrying a plurality of signals. The flexible cable 60 can be narrow to allow passage through a narrow gap. This allows the J-shaped interconnection between the stiffener block 76 and forward vertical carrier 48 to carry a very large number of signals through a narrow horizontal gap.

The flexible cable 60 can be attached to the stiffener block 76 and the forward vertical carrier 48, which are attached to a heat sink (not shown). The second circuit portion 64 can be adhesively bonded to the face of the forward vertical carrier 48 where the electronic components are mounted. The first circuit portion 62 can be adhesively bonded to the bottom face of the stiffener block 76. The second circuit portion 64 can be terminated in a profile around the LDA 56 and TIA 58 to match the shape of the LDA 56 and TIA 58 to provide ease of connection. The second circuit portion 64 can have wire bond pads in the area around the LDA 56 and TIA 58 to allow wire bonding to the dies.

For ease of fabrication, the stiffener block 76 and the forward vertical carrier 48 can both be laid on a flat surface, i.e., held in a single plane, during the initial assembly. The majority of the fabrication steps, including die bonding the electronic components to the blocks, attaching the flexible cable to the blocks, wire bonding the electronic components to the flexible cable, encapsulating the electronic components, and attaching a solder ball array, can be performed with the blocks on a flat surface. After those steps are completed, the assembly can be bent to form the 90-degree bend and the forward vertical carrier 48 attached to the vertical and horizontal portions of a heat sink.

The electronic components can be attached to the blocks by using standard die bond epoxy material and technique as will be appreciated by those skilled in the art. The flexible cable 60 can have wire bond pads to provide the electrical connection between the electrical components and the flexible cable.

The electronic components having the highest wiring density connection to the customer's interior board can be mounted in the stiffener block 76 closest to the solder ball array 82, which is used as the I/O interface and provides the connections to the customer's interior board. The receiver post amplifier 78 and eeprom 80 chips can be mounted in the stiffener block 76. The stiffener block 76 can have pockets for electronic components, which allow receiver post amplifier 78, eeprom 80, and any other electronic components to sit below the soldering plane, thus providing physical clearance to allow use of the solder ball interconnection facing the customer's host board. The receiver post amplifier 78 and eeprom 80 chips are wire bonded to the flexible cable 60 to provide electrical connection, and encapsulated with adhesive potting compound.

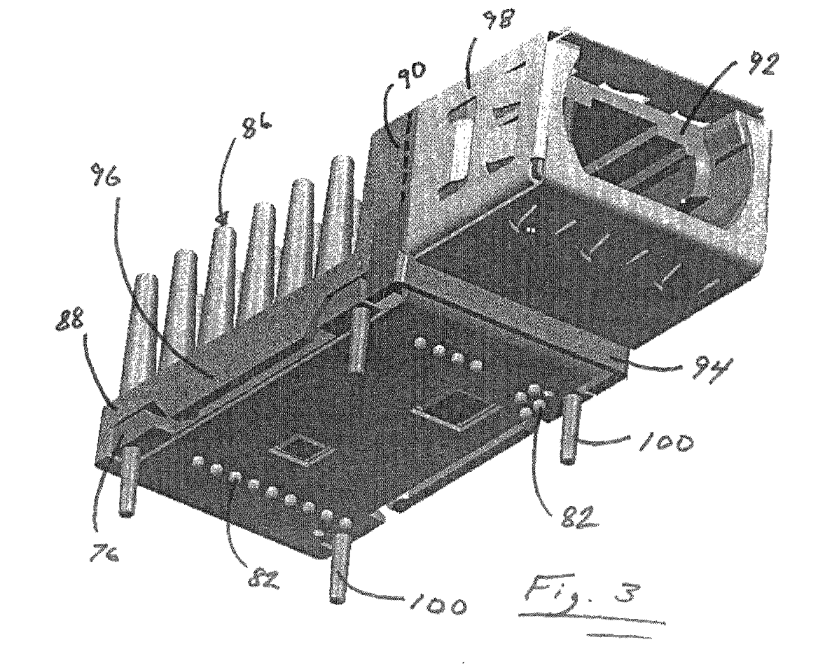

FIG. 3 shows an isometric diagram of a packaging architecture for a multiple array transceiver using a flexible cable made in accordance with the present invention.

The optical lens assembly is aligned and UV epoxy bonded to the forward vertical carrier (not shown). Precise alignment provides efficient optical signal transfer. The heat sink 86 provides the 90-degree angle between the forward vertical carrier and the stiffener block 76, as well as heat transfer from those elements. The stiffener block 76 and forward vertical carrier can be thermally connected to the heat sink 86 with adhesive, thermally conductive epoxy, or the like, as will be appreciated by those skilled in the art. The heat sink 86 can have fins, pins, vanes, passive cooling, or active cooling on the open surface to assist in heat transfer. The heat sink 86 can be made of any material with high thermal conductivity, such as aluminum or copper, and can be formed by various processes, such as die casting or machining. The heat sink 86 can also have a mating portion 96 to ease alignment and increase connection stability to the stiffener block 76.

The heat sink 86 incorporates a heat sink vertical portion 90 and a heat sink horizontal portion 88. The connection of the forward vertical carrier and the stiffener block 76 to the heat sink vertical portion 90 and a heat sink horizontal portion 88, respectively, provides the 90-degree angle between the forward vertical carrier and the stiffener block 76. This 90-degree configuration is required due to the right angle orientation between the customer's interior circuit board and the rear bulkhead of the chassis.

The heat sink 86 further comprises an upper retainer shell 92 to house a fiberoptic connector (not shown). After the forward vertical carrier has been assembled onto the heat sink 86, a lower retainer shell 94 is attached to the upper retainer shell 92. An EMI assembly clip 98 can be slid over the upper retainer shell 92 and the lower retainer shell 94. The EMI assembly clip 98 can provide both EMI and ground connection points to the customer chassis bulkhead.

This completes the assembly of the multiple array transceiver module. The module can be attached to the customer's board by reftow soldering the solder ball array 82 of the flexible cable 60 to mating pad locations on the customer board, and also by soldering the posts 100 that protrude from the stiffener block 76 through the customer's board.

It is important to note that the figures and description illustrate specific applications and embodiments of the present invention, and is not intended to limit the scope of the present disclosure or claims to that which is presented therein. While the figures and description present a 2.5 gigahertz, 4 channel transmit and 4 channel receive multiple array transceiver, the present invention is not limited to that format, and is therefore applicable to other array formats including dedicated transceiver modules, dedicated receiver modules, and modules with different numbers of channels. For example, other embodiments can include multiple in-line lasers and receivers or arrays of lasers and receivers, e.g., 8×8 or 16×16 grids. Upon reading the specification and reviewing the drawings hereof, it will become immediately obvious to those skilled in the art that myriad other embodiments of the present invention are possible, and that such embodiments are contemplated and fall within the scope of the presently claimed invention.

While the embodiments of the invention disclosed herein are presently considered to be preferred, various changes and modifications can be made without departing from the spirit and scope of the invention. The scope of the invention is indicated in the appended claims, and all changes that come within the meaning and range of equivalents are intended to be embraced therein.

1. A packaging architecture system for a transceiver comprising:
a forward vertical carrier having an optical converter;
a stiffener block, the stiffener block oriented about 90 degrees from the forward vertical carrier; and
a flexible cable electrically connecting the optical converter of the forward vertical carrier to a solder ball array aligned with the stiffener block.

2. The system of claim 1 wherein the optical converter is at least one laser.

3. The system of claim 1 wherein the optical converter is at least one photodetector.

4. The system of claim 1 further comprising an electronic component die thermally connected to the forward vertical carrier.

5. The system of claim 1 further comprising an electronic component die thermally connected to the stiffener block.

6. The system of claim 1 further comprising a heat sink thermally connected to the forward vertical carrier and the stiffener block.

7. A packaging architecture system for a transceiver comprising:
first means for supporting an optical converter;
second means for supporting an electrical connection, the second supporting means oriented about 90 degrees from the first supporting means; and
means for a electrically connecting the optical converter and the electrical connection.

8. The system of claim 7 wherein the optical converter is at least one laser.

9. The system of claim 7 wherein the optical converter is at least one photodetector.

10. The system of claim 7 further comprising an electronic component die thermally connected to the first supporting means.

11. The system of claim 7 further comprising an electronic component die thermally connected to the second supporting means.

12. The system of claim 7 further comprising means for removing heat thermally connected to the first supporting means and the second supporting means.

13. The system of claim 7 further comprising means for removing heat, the heat removing means having a heat sink vertical portion and a heat sink horizontal portion, the heat sink vertical portion being attached to the second supporting means and the heat sink horizontal portion being attached to the second supporting means.

14. A packaging architecture system for a transceiver comprising:
a heat sink, the heat sink having a first surface and a second surface, the first surface being oriented about 90 degrees from the second surface;
a forward vertical carrier having an optical converter, the forward vertical carrier being attached to the first surface of the heat sink;
a stiffener block, the stiffener block being attached to the second surface of the heat sink;
a rearward horizontal I/O block, the rearward horizontal I/O block being attached to the stiffener block; and
a flexible cable electrically connecting the optical converter of the forward vertical carrier to a solder ball array aligned with the stiffener block.

15. The system of claim 14 wherein the optical converter comprises at least one laser.

16. The system of claim 14 wherein the optical converter is at least one photodetector.

17. The system of claim 14 further comprising an electronic component die thermally connected to the forward vertical carrier.

18. The system of claim 17 wherein the electronic component is selected from the group consisting of a laser drive amplifier and a transimpedance amplifier.

19. The system of claim 14 further comprising an electronic component die thermally connected to the stiffener block.

20. The system of claim 19 wherein the electronic component is selected from the group consisting of a receiver post amplifier and an eeprom.
